(19) United States
(12) Patent Application Publication
(10) Pub. No.: US 2003/0168278 A1
(43) Pub. Date: Sep. 11, 2003

(54) Housing for a hands-free directional microphone

(75) Inventor: Thomas Solderits, Wien (AT)

Correspondence Address: Friedrich Kueffner, Suite 910, 317 Madison Avenue, New York, NY, 10017, US

(73) Assignee: AKG Acoustics GmbH

(21) Appl. No.: 10/382,716

(22) Filed: Mar. 6, 2003

(30) Foreign Application Priority Data
Mar. 7, 2002 (AU) A 363/2002

(51) Int. Cl. H05K 5/00; H04R 7/00; G10K 13/00; F01N 7/00

(52) U.S. Cl. 181/153; 181/158; 181/242

(57) ABSTRACT

A microphone housing to be mounted in a vehicle and having an electroacoustic transducer of a microphone arranged in the microphone housing has at least one sound entry opening, wherein the microphone housing when mounted projects past a surrounding surface of a component of the vehicle in which the microphone housing is mounted. The at least one sound entry, in the mounted state of the microphone housing, is positioned closely above the surrounding surface.

### BACKGROUND OF THE INVENTION

1. Field of the Invention

The invention relates to a housing for a microphone, in particular, a hands-free microphone, having at least one sound entry opening and comprising an electroacoustic transducer, preferably a directional transducer, arranged in the microphone housing. The housing is designed for fixed installation particularly in a mounting module, a console, or an interior panel of a motor vehicle.

2. Description of the Related Art

Hands-free microphones for use in connection with cellular telephones or for internal communication within a vehicle are supposed to transmit the useful sound generated by the speaking person and are supposed to suppress noise of other sound sources, such as the motor noise and driving noise, in order to ensure easy understanding of the speaking person. For this purpose, advantageously directional microphones can be used which however have disadvantages. They have an increased structure-borne noise sensitivity and they generate disruptive noise when they are operated in airflows, for example, generated by vehicle ventilation systems or by relative wind when the windows of the vehicle are rolled down or when the vehicle is a convertible.

The use of hands-free microphone devices in vehicles represents a significant contribution to traffic safety. However, proper understanding of the speaking person often is impaired by the disruptive noise coming from different sources; this can impair concentration on the conversation and also the necessary concentration on the traffic. While the quality of radio transmission is usually satisfactory, the quality of speech recording by the microphone is often unsatisfactory.

Conventionally, directional microphones are surrounded for reducing the disruptive background noises with shaped plastic bodies made of open-pore foam material which have the effect of calming the turbulent flow to the microphone diaphragm. The effect of the flow noises generated at the foam surface can be reduced by enlarging the size of the foam body. However, the frequency range and the directional characteristics of the microphone are negatively affected in this way. In vehicles, the use of such arrangements is also restricted because of the limited space available and the need for keeping the field of view of the driver unimpaired.

European patent application 0 707 403 A describes in connection with hand-held devices the installation of microphone capsules inside an acoustic filter for reducing the wind noise. The filter is comprised of chambers and connecting channels; the mounting location for the microphone capsule as well as the location for entry of sound are precisely predetermined. This mounting arrangement can be produced only with expensive measures and requires also a lot of space. The problem of structure-borne sound, which usually plays no role in the case of hand-held devices, is furthermore aggravated rather than resolved by these measures.

Therefore, there is a need for microphones which can be mounted easily without requiring more space in the surroundings of the driver's seat of a motor vehicle and which, with respect to structure-borne sound as well as with respect to wind noise, have improved properties compared to conventional microphones.

### SUMMARY OF THE INVENTION

It is an object of the present invention to provide a microphone fulfilling the above defined requirements.

In accordance with the present invention, this is achieved in that the microphone capsule is elastically supported in a housing which in the mounted state projects partially past the surface of the mounting module, the console or the interior panel of the motor vehicle and which has sound entry locations which are provided in the area of this surface or in its direct vicinity.

In this way, on the one hand, it is possible to reduce significantly structure-borne sound and, on the other hand, to ensure that the sound entry is in the area of the surface of the surroundings of the housing and thus in an area in which possibly occurring airflow is laminar so that wind noise is eliminated in a simple and reliable way.

### BRIEF DESCRIPTION OF THE DRAWING

In the drawing:

FIG. 1 shows a housing according to the invention in a side view;

FIG. 2 shows the housing of FIG. 1 in a perspective view.

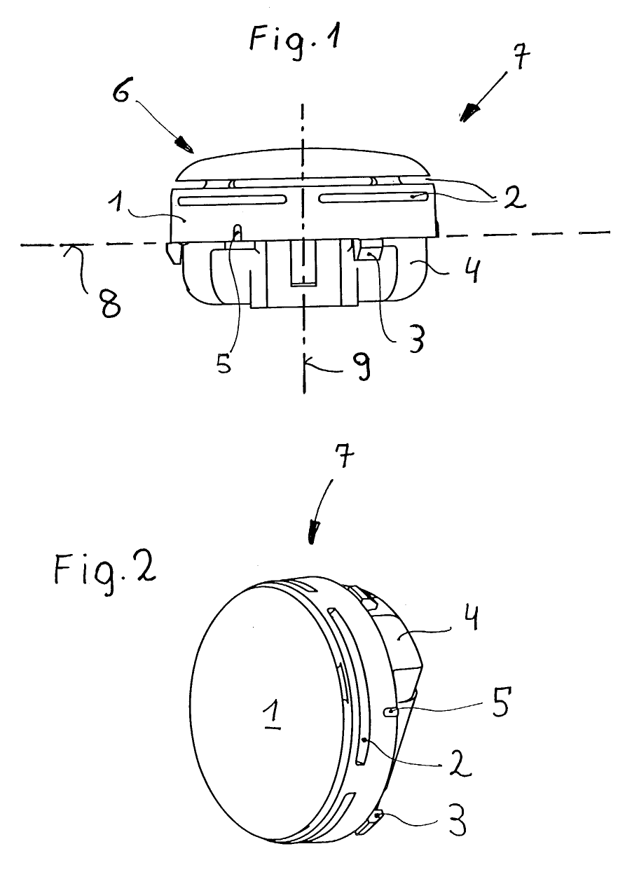

### DESCRIPTION OF THE PREFERRED EMBODIMENTS

In the illustrated embodiment the housing 7 is comprised of two parts, the base part 4 and the cover 1. The cover 1 has slots 2 which are positioned in planes perpendicular to the central axis 9 of the housing 7 and are thus parallel to the schematically illustrated surface 8 of the part of the vehicle in which the microphone is installed. This surface is positioned approximately in the area in which the cover 1 is connected to the base part 4. The slots 2 are positioned, as indicated above, so closely above the surrounding surface that they are positioned within the area of a laminar boundary layer. This laminar boundary layer will form for any type of flow on surfaces which are in the area of the flow and is characterized by the lack of turbulence and thus the lack of wind noise.

With these measures it is made possible to eliminate the previously required large-volume wind protection of foam material, which is mechanically rather weak, and it is achieved that the frequency range and thus the characteristics of the transducer are not affected in this way.

In the interior of the housing a directional transducer is elastically supported. Its directional characteristics are oriented transversely to the symmetry axis of the housing. The configuration and securing of the transducer has no relevance with regard to the present invention so that no detailed explanation is provided in this context. A person skilled in the art of microphone technology will be able, in knowledge of the present invention, to provide a corresponding solution which meets the respective requirements. The elastic support can be realized by a “flying suspension” on several rubber-elastic arms, by elastic support elements, or any other suitable means known in the prior art. The slots 2 can be covered in the interior of the housing in a way known in the art by acoustic damping material (open-pore foam material, non-woven material); in addition to acoustic effects, this also prevents penetration of dust and particles into the microphone.

The housing can be provided with fastening elements 3 on the housing part 4 or on the cover 1. When the microphone is mounted “on contact” by insertion into a bore of a wall, a mounting module or a console, the attachment elements 3, as illustrated, can be snap-on hooks on the cover 1 which support the microphone against tensile forces. When the microphone is to be mounted freely in an interior panel or a wall element, a collar provided on the cover extending about its periphery can receive the pressure forces. Axially oriented ribs 5 on the outer periphery of the cover 1 or of the base part 4, depending on the configuration, can be provided for compensating possibly present tolerances.

A particularly beneficial effect of the wind protection is achieved in that the cover by means of an elliptical shape 6 and the lack of sharp edges or corners does not disrupt laminar flow.

The configuration and the thickness of the laminar boundary layer depends on the occurring flows, the roughness of the surface, the pressure changes in the surroundings of the area in question and the like. For a person skilled in the art of flow dynamics, it is easily possible in knowledge of the invention, based on the available data of the respective mounting situation, to estimate the thickness of the laminar boundary layer, if necessary, to determine the thickness by means of a few simple experiments, and to then select the arrangement of the slots 2 on the housing 7 accordingly.

The invention is not limited to the described and illustrated embodiment but can be modified in various ways. For example, in particular the slots (or other sound entry openings formed differently) can be arranged in the base part, and the cover then takes over substantially only a covering function. Also, the sound entry openings must not have the shape of slots but can also be oval, circular, or polygonal openings and the like. The housing can be comprised of any material of which housings for electroacoustic transducers are made in the prior art. Mounting can be realized in other ways than by means of the illustrated hooks, for example, by means of an adhesive.

It is important that the sound entry takes place only within areas positioned within the laminar boundary layer of the surrounding surface. The sound entry openings are therefore positioned entirely within the area of this boundary layer.

While specific embodiments of the invention have been shown and described in detail to illustrate the inventive principles, it will be understood that the invention may be embodied otherwise without departing from such principles.

What is claimed is:

1. A microphone housing to be mounted in a vehicle, wherein an electroacoustic transducer of a microphone is arranged in the microphone housing; the microphone housing comprising:
at least one sound entry opening, wherein the microphone housing when mounted projects past a surrounding surface of a vehicle component in which the microphone housing is mounted;
wherein the at least one sound entry, in the mounted state of the microphone housing, is positioned closely above the surrounding surface.

2. The microphone housing according to claim 1, wherein the at least one sound entry opening is positioned in an area of a laminar boundary layer of the surrounding surface.

3. The microphone housing according to claim 1, wherein the at least one sound entry opening is a slot.

4. The microphone housing according to claim 1, wherein the microphone housing is rotationally symmetrical and wherein the at least one sound entry opening is arranged symmetrically about a center axis of the microphone housing.

5. The microphone housing according to claim 1, wherein the microphone housing has an elliptical cross-section in a plane of the surrounding surface.

6. The microphone housing according to claim 1, wherein the microphone housing has a polygonal cross-section with rounded corners in a plane of the surrounding surface.

7. The microphone housing according to claim 1, comprised of a base part and a cover, wherein at least one of the base part and the cover has fastening elements.

8. The microphone housing according to claim 1, having a periphery provided with ribs located in the mounted state in the area of the vehicle component surrounding the microphone housing.

9. The microphone housing according to claim 1, wherein the microphone housing has a radially projecting shoulder in a plane of the surrounding surface.

10. The microphone housing according to claim 1, having a surface roughness which is small in comparison to a thickness of the laminar boundary layer of the surrounding surface.

11. The microphone housing according to claim 1, being free of any edges or corners disturbing a laminar boundary layer of the surrounding surface.

12. The microphone housing according to claim 1, wherein the electroacoustic transducer is a directional transducer.

13. The microphone housing according to claim 1, wherein the microphone is a hands-free microphone.
